(19) United States
(12) Patent Application Publication
(10) Pub. No.: US 2014/0118977 A1
(43) Pub. Date: May 1, 2014

(54) WIRING BOARD

(71) Applicant: Murata Manufacturing Co., Ltd., Nagaokakyo-shi (JP)

(72) Inventors: Satoshi ITO, Nagaokakyo-shi (JP); Yoichi MORIYA, Nagaokakyo-shi (JP); Tetsuo KANAMORI, Nagaokakyo-shi (JP); Yukihiro YAGI, Nagaokakyo-shi (JP); Yuki YAMAMOTO, Nagaokakyo-shi (JP)

(73) Assignee: MURATA MANUFACTURING CO., LTD., Nagaokakyo-shi (JP)

(21) Appl. No.: 14/147,611

(22) Filed: Jan. 6, 2014

Related U.S. Application Data
(63) Continuation of application No. PCT/JP2012/065719, filed on Jun. 20, 2012.

(30) Foreign Application Priority Data
Jul. 8, 2011 (JP) 2011-151430

(51) Int. Cl. H05K 1/11

(52) U.S. Cl. CPC H05K 1/115
USPC 361/767; 174/261; 174/255; 174/251

(57) ABSTRACT

A wiring board includes an insulating layer, and an upper wiring pattern and a lower wiring pattern arranged with the insulating layer interposed therebetween. A truncated cone-shaped projection is integral with the lower wiring pattern so as to project at the upper wiring pattern side, and a truncated cone-shaped projection is integral with the upper wiring pattern so as to project at the lower wiring pattern side. Bonding end portions of the projections are bonded to each other to form an inter-layer connection conductor. The inter-layer connection conductor conducts the upper wiring pattern and the lower wiring pattern.

### BACKGROUND OF THE INVENTION

1. Field of the Invention

The present invention relates to a wiring board in which a conductor pattern is located on an insulating layer.

2. Description of the Related Art

In a wiring board, an inter-layer connection conductor (via-hole conductor) which electrically connects wiring patterns on different layers is formed generally by providing a penetration hole (through hole) in the wiring board and applying plating to an inner wall of the through hole. However, when adhesion of the plating to the through hole is poor, a problem with reliability at the through hole arises, such as peeling or cutting of the plating by stress generated during heating or cooling.

Japanese Unexamined Patent Application Publication No. 2000-68641 discloses a method for manufacturing a printed wiring board having excellent reliability at a through hole. FIG. 1 is a schematic cross-sectional view of the wiring board described in Japanese Unexamined Patent Application Publication No. 2000-68641. For the printed wiring board shown in FIG. 1, truncated cone-shaped projections 101 to which a silver paste 101A adheres are formed on one surface of a metal plate 100, an insulating layer 102 is formed at the projection side, a metal foil 103 is placed on an outer side portion of the insulating layer 102, and laminate molding is conducted under heating and pressurization. Then, circuit formation and noble metal plating are conducted on the metal plates 103 and 104 on both surfaces, whereby a printed wiring board is formed. In Japanese Unexamined Patent Application Publication No. 2000-68641, the trapezoidal projections 101 formed on the metal plate 100, not plating applied to an inner wall of a through hole, are made into via-hole conductors, whereby peeling of plating or the like is not caused during heating or cooling and a decrease in reliability at a through hole is prevented.

In Japanese Unexamined Patent Application Publication No. 2000-68641, however, the trapezoidal projections 101 on the metal plate 100 which are made into via-hole conductors spread or extend significantly in a plane direction of the wiring board, and thus there is a problem that the trapezoidal projections 101 have an adverse effect on size reduction of the wiring board. This problem prominently appears as the height in the thickness direction of the wiring board, namely, the height of each trapezoidal projection 101, is increased.

### SUMMARY OF THE INVENTION

Therefore, preferred embodiments of the present invention provide a wiring board which prevents decrease in reliability at an inter-layer connection conductor such that an adverse effect on size reduction is prevented from occurring.

A wiring board according to a preferred embodiment of the present invention includes an insulating layer, a first conductive pattern and a second conductive pattern arranged with the insulating layer interposed therebetween and extending in a plane direction; and an inter-layer connection conductor extending through the insulating layer in a thickness direction to connect the first conductive pattern and the second conductive pattern. The inter-layer connection conductor includes portions which are thinned from the first conductive pattern and the second conductive pattern toward the first conductive pattern and the second conductive pattern which are opposed to each other in the thickness direction.

In this configuration, the inter-layer connection conductor which connects the first conductive pattern and the second conductive pattern is configured to include the portions which are thinned toward a center portion in the thickness direction. Therefore, as compared to the case with a trapezoidal shape as in the related art, it is possible to prevent or significantly reduce the spread of the board in the plane direction even when the height is increased, and it is possible to achieve size reduction of the wiring board.

In the wiring board according to the present invention, the inter-layer connection conductor may be formed by bonding end portions of two connection conductors which are thinned toward ends thereof.

In this configuration, the inter-layer connection conductor is preferably formed by bonding end portions of two connection conductors which are thinned toward ends thereof. When the heights of the two connection conductors are made the same, it is possible to minimize or significantly reduce the spread in the plane direction, and it is possible to achieve further size reduction of the wiring board.

In the wiring board according to a preferred embodiment of the present invention, preferably, one of the two connection conductors is integral with the first conductive pattern so as to project in the thickness direction at the second conductive pattern side, and the other of the two connection conductors preferably is integral with the second conductive pattern so as to project in the thickness direction at the first conductive pattern side.

In this configuration, since the inter-layer connection conductor preferably is integral with the first conductive pattern and the second conductive pattern, there is no bonding interface with the inter-layer connection conductor in the first conductive pattern and the second conductive pattern. It should be noted that “integral” means to be formed from the same single metal member so as to define a single unitary member.

By expansion and contraction with temperature change (superheating and cooling), stress occurs in a bonded portion of the insulating layer and each conductive pattern due to a difference in expansion coefficient therebetween. If there is a bonding interface between the inter-layer connection conductor and the first conductive pattern or the second conductive pattern, generated stress is concentrated on the bonding interface, and there is a concern that peeling occurs at the bonding interface. Thus, there is a possibility that conduction failure occurs between the first conductive pattern and the second conductive pattern or a crack or the like occurs in the wiring board.

Thus, since the connection conductors which define the inter-layer connection conductor are integral with the first conductive pattern and the second conductive pattern, respectively, it is possible to prevent conduction failure due to peeling, a crack occurring in the wiring board, and the like.

In addition, when the first conductive pattern and the second conductive pattern are connected to each other by plating being applied to an inner wall of a through hole as in the related art, a resistance value at the connection portion is increased. On the other hand, as in preferred embodiments of the present invention, since the inter-layer connection conductors which define the inter-layer connection conductor are integral with the first conductive pattern and the second conductive pattern, a resistance value at the connection portion is not increased and thus it is possible to avoid such a problem.

In the wiring board according to a preferred embodiment of the present invention, the first conductive pattern may include a land that is integrally formed at the insulating layer side, and the wiring board may further include an electronic component mounted on the land and arranged within the insulating layer.

As described above, the spread of the inter-layer connection conductor of the present invention in the plane direction is small. Thus, this configuration is advantageous in that it is possible to reduce the size of the wiring board when the electronic component is incorporated into the insulating layer.

According to various preferred embodiments of the present invention, it is possible to prevent a decrease in reliability at an inter-layer connection conductor such that an adverse effect on size reduction of a wiring board is prevented from occurring.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic cross-sectional view of a wiring board described in Japanese Unexamined Patent Application Publication No. 2000-68641.

FIG. 2 is a schematic cross-sectional view of a wiring board according to Preferred Embodiment 1 of the present invention.

FIG. 3A is a schematic diagram showing, in sequence, steps for manufacturing the wiring board according to Preferred Embodiment 1 of the present invention.

FIG. 3B is a schematic diagram showing, in sequence, the steps for manufacturing the wiring board according to Preferred Embodiment 1 of the present invention.

FIG. 3C is a schematic diagram showing, in sequence, the steps for manufacturing the wiring board according to Preferred Embodiment 1 of the present invention.

FIG. 3D is a schematic diagram showing, in sequence, the steps for manufacturing the wiring board according to Preferred Embodiment 1 of the present invention.

FIG. 3E is a schematic diagram showing, in sequence, the steps for manufacturing the wiring board according to Preferred Embodiment 1 of the present invention.

FIG. 4 is a schematic cross-sectional view of a wiring board according to Preferred Embodiment 2 of the present invention.

FIG. 5A is a schematic diagram showing, in sequence, steps for manufacturing the wiring board according to Preferred Embodiment 2 of the present invention.

FIG. 5B is a schematic diagram showing, in sequence, the steps for manufacturing the wiring board according to Preferred Embodiment 2 of the present invention.

FIG. 5C is a schematic diagram showing, in sequence, the steps for manufacturing the wiring board according to Preferred Embodiment 2 of the present invention.

FIG. 5D is a schematic diagram showing, in sequence, the steps for manufacturing the wiring board according to Preferred Embodiment 2 of the present invention.

FIG. 6A is a schematic diagram showing, in sequence, the steps for manufacturing the wiring board according to Preferred Embodiment 2 of the present invention.

FIG. 6B is a schematic diagram showing, in sequence, the steps for manufacturing the wiring board according to Preferred Embodiment 2 of the present invention.

FIG. 7 is a schematic cross-sectional view of a wiring board according to Preferred Embodiment 3 of the present invention.

FIG. 8A is a schematic diagram showing, in sequence, steps for manufacturing the wiring board according to Preferred Embodiment 3 of the present invention.

FIG. 8B is a schematic diagram showing, in sequence, the steps for manufacturing the wiring board according to Preferred Embodiment 3 of the present invention.

FIG. 8C is a schematic diagram showing, in sequence, the steps for manufacturing the wiring board according to Preferred Embodiment 3 of the present invention.

FIG. 8D is a schematic diagram showing, in sequence, the steps for manufacturing the wiring board according to Preferred Embodiment 3 of the present invention.

FIG. 8E is a schematic diagram showing, in sequence, the steps for manufacturing the wiring board according to Preferred Embodiment 3 of the present invention.

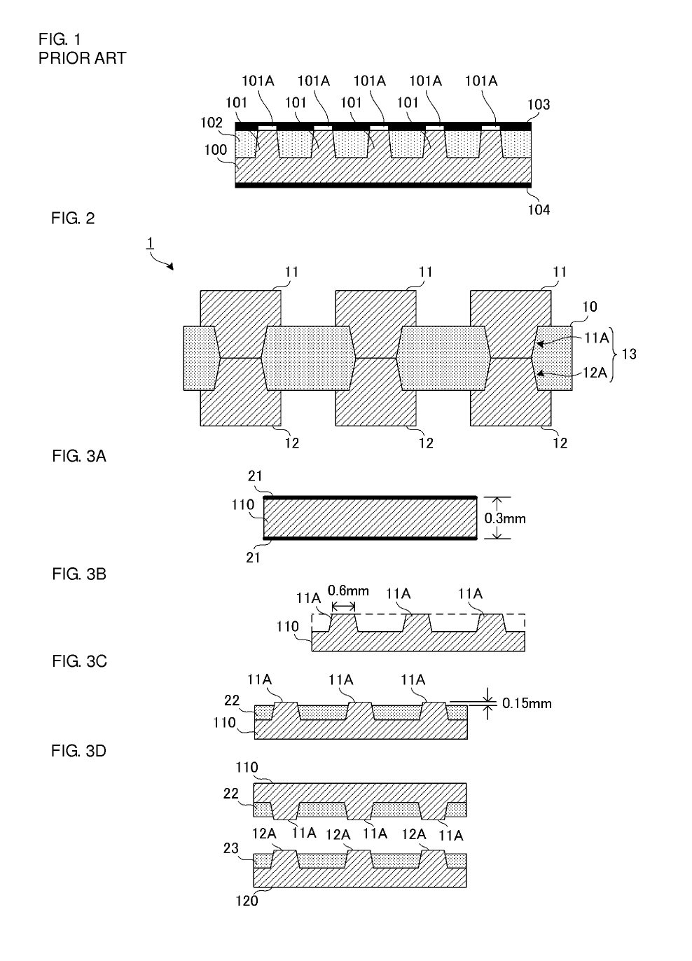

### DETAILED DESCRIPTION OF THE PREFERRED EMBODIMENTS

A wiring board according to preferred embodiments of the present invention includes an insulating layer made from an insulating resin and a conductive wiring pattern (conductive pattern) provided on the insulating layer. The insulating layer may be a single layer or a plurality of layers. In addition, examples of the insulating resin forming the insulating layer include a glass epoxy resin, an epoxy resin, a phenolic resin, a cyanate resin, etc. In particular, an epoxy resin is preferred since adhesiveness and strength thereof are excellent.

The wiring board electrically connects an electronic component mounted on a surface of the insulating layer via the wiring pattern and a main board (e.g., a motherboard) on which the wiring board is mounted. Examples of the electronic component mounted on the wiring board include an active element such as a silicon semiconductor element or a gallium arsenide semiconductor element or a passive element such as a capacitor or an inductor.

### Preferred Embodiment 1

FIG. 2 is a schematic cross-sectional view of a wiring board according to Preferred Embodiment 1 of the present invention. The wiring board 1 according to Preferred Embodiment has a configuration in which an upper wiring pattern 11 is located on an upper surface of an insulating layer 10 and a lower wiring pattern 12 is located on a lower surface of the insulating layer 10.

The insulating layer 10 preferably has a thickness of about 0.10 mm, for example. The upper wiring pattern 11 is located on the upper surface of the insulating layer 10, and the lower wiring pattern 12 is located on the lower surface of the insulating layer 10. The upper wiring pattern 11 and the lower wiring pattern 12 each preferably have a thickness of about 0.10 mm, for example, and are located at positions which substantially coincide with each other in the thickness direction of the insulating layer 10.

Projections 11A are integral with the upper wiring pattern 11 so as to project at a lower side along the thickness direction, that is, at the lower wiring pattern 12 side. In other words, the upper wiring pattern 11 and the projections 11A are preferably formed from the same metal member, and there is no bonding interface therebetween. The projections 11A have a height (a length in the thickness direction) that extends up to substantially a center between the upper wiring pattern 11 and the lower wiring pattern 12 and have a truncated cone shape which is gradually thinned toward the lower wiring pattern 12 side. The diameter of an end portion (hereinafter, referred to as bonding end portion) of each projection 11a at the lower wiring pattern 12 side preferably is about 0.6 mm, for example. It should be noted that each projection 11a may have a square pole shape with a trapezoidal lateral surface.

In addition, projections 12A are integral the lower wiring pattern 12 so as to project at the upper wiring pattern side. In other words, the lower wiring pattern 12 and the projections 12A are preferably formed from the same metal member, and there is no bonding interface therebetween. The projections 12A preferably have substantially the same shapes as those of the projections 11A.

The projections 11A of the upper wiring pattern 11 and the projections 12A of the lower wiring pattern 12 are bonded to each other such that the bonding end portions thereof are brought into close contact with each other. Hereinafter, a portion obtained by bonding each projection 11A and each projection 12A is referred to as an inter-layer connection conductor 13. The upper wiring pattern 11 and the lower wiring pattern 12 are conducted to each other via the inter-layer connection conductor 13.

Since each inter-layer connection conductor 13 is preferably formed by bonding the two projections 11A and 12A as described above, it is possible to make the heights of the projections 11A and 12A to be about ½ of the distance between the upper wiring pattern 11 and the lower wiring pattern 12, for example. As a result, it is possible to reduce the spread of the projections 11A and 12A in a direction perpendicular or substantially perpendicular to the thickness direction of the insulating layer 10 (hereinafter, referred to as plane direction), as compared to the case where each inter-layer connection conductor 13 is formed from a single member. Thus, size reduction of the wiring board 1 is made possible.

In addition, since the projections 11A and 12A are preferably formed integrally with the upper wiring pattern 11 and the lower wiring pattern 12, respectively, no bonding interface is present in any location except between the projections 11A and 12A. Thus, it is possible to prevent conduction failure due to peeling which is caused by stress generated due to a difference in expansion coefficients, a crack occurring in the wiring board 1, and the like, and it is possible to improve connection reliability at each inter-layer connection conductor 13.

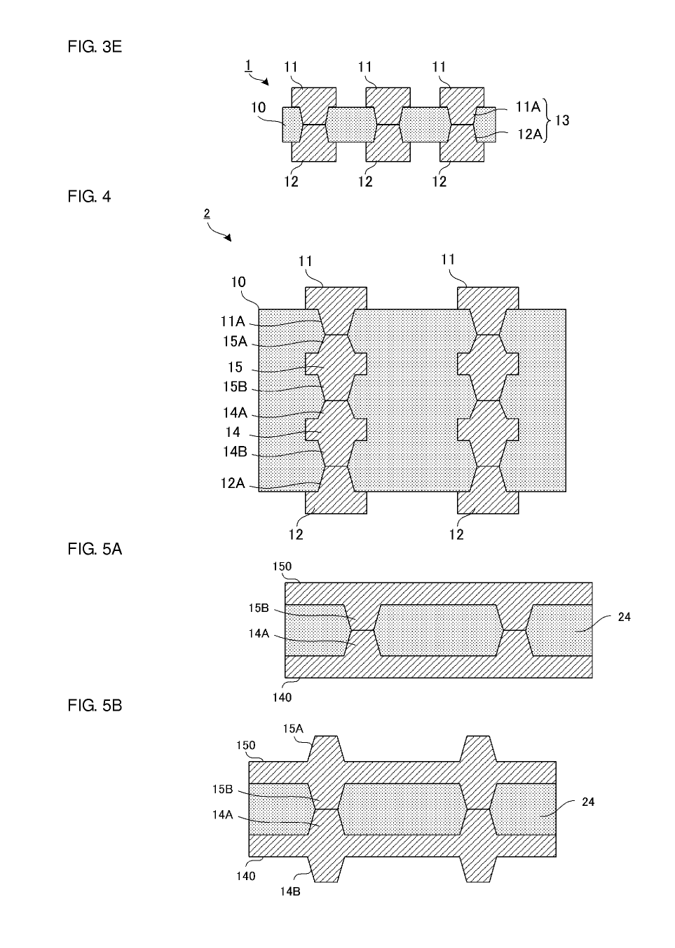

Next, a non-limiting example of a method for manufacturing the wiring board 1 will be described. FIG. 3A, FIG. 3B, FIG. 3C, FIG. 3D, and FIG. 3E are schematic diagrams showing, in sequence, steps for manufacturing the wiring board 1 according to Preferred Embodiment 1. From a first step to a third step, two components which are the same, namely, the upper wiring pattern 11 side and the lower wiring pattern 12 side in FIG. 2, are manufactured. Hereinafter, the upper wiring pattern 11 will be described, and for the lower wiring pattern 12, the corresponding reference signs will be indicated in parentheses.

In the initial first step (FIG. 3A), dry film resists 21 having a thickness of 15 μm are attached to both surfaces of a 0.3 mm-thick copper plate 110 which are opposed to each other in a thickness direction thereof. It should be noted that FIG. 3A, FIG. 3B, FIG. 3C, FIG. 3D, and FIG. 3E are views as seen from a lateral surface direction of the copper plate 110.

Next, in the second step (FIG. 3B), etching is conducted on one surface of the copper plate 110 on which the dry film resist 21 is attached, such that truncated cone-shaped projections 11A (12A) whose bonding end portions have a diameter of 0.6 mm remain. In addition, the dry film resist 21 is peeled off after the etching.

In the third step (FIG. 3C), an insulating resin 22 is applied to the copper plate 110 that has been subjected to the etching in the second step. At that time, the projections 11A (12A) are formed into a state of projecting from the insulating resin 22 (23) by 0.05 mm. The insulating resins 22 and 23 become the above-described insulating layer 10.

In a fourth step (FIG. 3D), the workpieces manufactured until the third step are arranged such that the projections 11A and 12A face each other, and the bonding end portions of the projections 11A and the projections 12A are brought into close contact with each other. In this state, they are pressure-bonded by conducting heating and pressurization for 1 hour at 180° C. and 10 MPa. Thus, one inter-layer connection conductor 13 obtained by connecting the projections 11A and 12A is formed.

In a fifth step (FIG. 3E), the laminate obtained in the fourth step is crimped and pressed, and then pattern formation is conducted on both surfaces of the laminate by a subtractive method (a method of removing unwanted portions to leave a circuit), such that an upper wiring pattern 11 and a lower wiring pattern 12 are formed. Thus, a wiring board 1 is formed.

Since the inter-layer connection conductor 13 is formed by bonding the two projections 11A and 12A as described above, it is possible to reduce the spread of the wiring board 1 in the plane direction, and it is possible to achieve size reduction of the wiring board 1. In addition, the projections 11A and 12A are formed integrally with the upper wiring pattern 11 and the lower wiring pattern 12, respectively. In other words, no bonding interface is present in any location except between the projections 11A and 12A. Thus, it is possible to prevent conduction failure due to peeling which is caused by stress generated due to a difference in expansion coefficient, a crack occurring in the wiring board 1, and the like, and it is possible to improve connection reliability at each inter-layer connection conductor 13.

It should be noted that a conductive adhesive may be applied to the bonding interface between the projections 11A of the upper wiring pattern 11 and the projections 12A of the lower wiring pattern 12. The conductive adhesive is, for example, a low-resistance conductive paste of nanosilver or nanocopper. It should be noted that the conductive adhesive may be a resin composition containing metal powder. When the conductive adhesive is applied, it is possible to further improve the connection reliability at each inter-layer connection conductor 13.

### Preferred Embodiment 2

Next, a wiring board according to Preferred Embodiment 2 of the present invention will be described. The wiring board according to Preferred Embodiment 2 is different from Preferred Embodiment 1 in that a wiring pattern is further laminated between the upper wiring pattern 11 and the lower wiring pattern 12. Hereinafter, only the difference will be described.

FIG. 4 is a schematic cross-sectional view of the wiring board according to Preferred Embodiment 2. In the wiring board 2 according to Preferred Embodiment 2, as shown in FIG. 4, a first intermediate layer wiring pattern 14 and a second intermediate layer wiring pattern 15 are further laminated between the upper wiring pattern 11 and the lower wiring pattern in the insulating layer 10. The first intermediate layer wiring pattern 14 is laminated at the lower wiring pattern 12 side, and the second intermediate layer wiring pattern 15 is laminated at the upper wiring pattern 11 side. In other words, the upper wiring pattern 11, the second intermediate layer wiring pattern 15, the first intermediate layer wiring pattern 14, and the lower wiring pattern 12 are laminated in order from the upper surface side of the insulating layer 10.

Projections 14A preferably are formed integrally with the first intermediate layer wiring pattern 14 so as to project at the second intermediate layer wiring pattern 15 side, and projections 14B preferably are formed integrally with the first intermediate layer wiring pattern 14 so as to project at the upper wiring pattern 11 side. In other words, the first intermediate layer wiring pattern 14 and the projections 14A and 14B are formed from the same metal member, and there is no bonding interface therebetween. The projections 14A and 14B have the same shapes and sizes as those of the projections 11A and the projections 12A. A bonding end portion of each projection 14A is bonded to that of a projection 15B of the second intermediate layer wiring pattern 15 described later. A bonding end portion of each projection 14B is bonded to that of the projection 12A of the lower wiring pattern 12.

Projections 15A preferably are formed integrally with the second intermediate layer wiring pattern 15 so as to project at the upper wiring pattern 11 side, and projections 15B preferably are formed integrally with the second intermediate layer wiring pattern 15 so as to project at the first intermediate layer wiring pattern 14 side. In other words, the second intermediate layer wiring pattern 15 and the projections 15A and 15B preferably are formed from the same metal member, and there is no bonding interface therebetween. The projections 15A and 15B have the same shapes and sizes as those of the projections 11A and the projections 12A. A bonding end portion of each projection 15A is bonded to that of the projection 11A of the upper wiring pattern 11. In addition, a bonding end portion of each projection 15B is bonded to that of the projection 14A of the first intermediate layer wiring pattern 14.

The upper wiring pattern 11 and the second intermediate layer wiring pattern 15 are conducted to each other via the projections 11A and 15A. The first intermediate layer wiring pattern 14 and the second intermediate layer wiring pattern 15 are conducted to each other via the projections 15B and 14A. The first intermediate layer wiring pattern 14 and the lower wiring pattern 12 are conducted to each other via the projections 14B and 12A.

Since the wiring patterns are incorporated into the insulating layer 10 to make the insulating layer 10 multilayered as described above, it is possible to prevent or significantly reduce an increase in the size of the wiring board 2 in the plane direction, and it is possible to achieve size reduction of the wiring board 2.

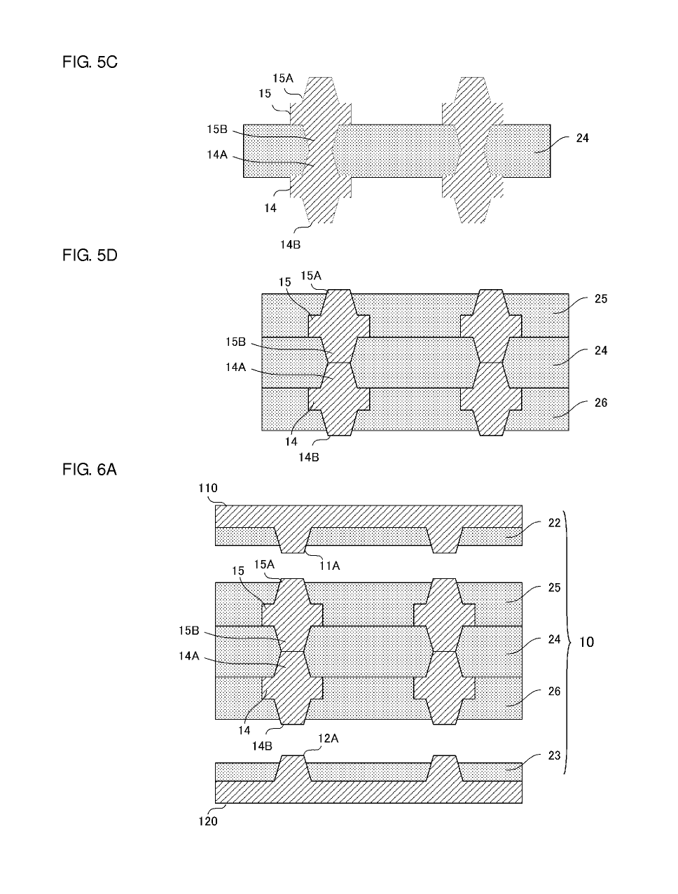

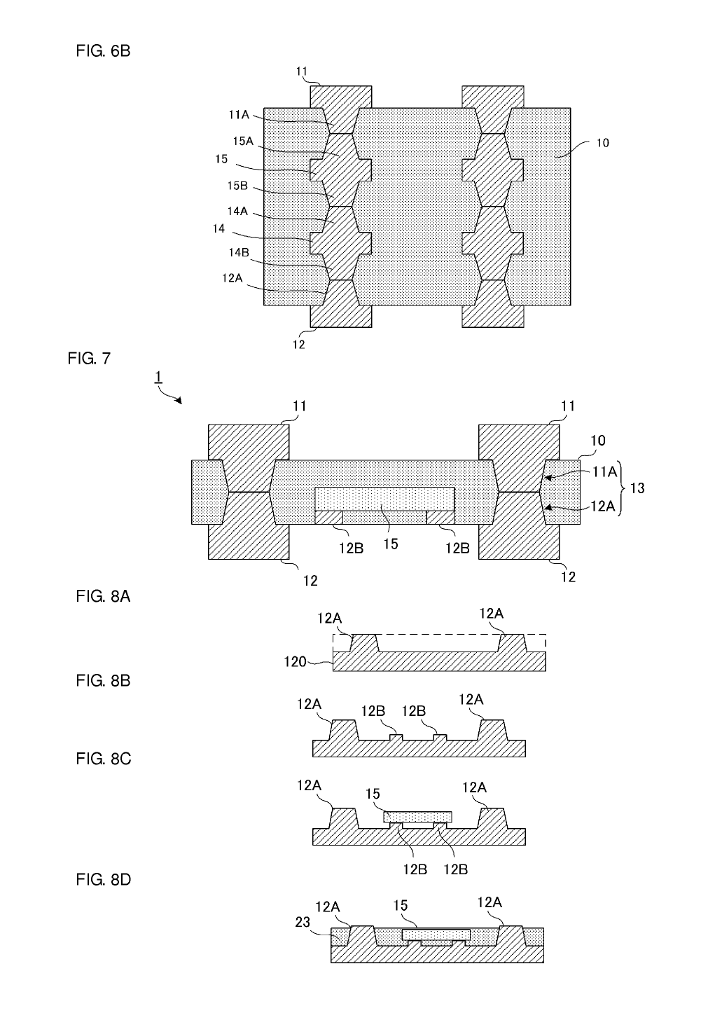

Hereinafter, a non-limiting method for manufacturing the wiring board 2 according to Preferred Embodiment 2 will be described. FIG. 5A, FIG. 5B, FIG. 5C, and FIG. 5D, and FIG. 6A and FIG. 6B are schematic diagrams showing, in sequence, steps for manufacturing the wiring board 2 according to Preferred Embodiment 2.

The manufacturing steps from FIG. 3A to FIG. 3C as described in Preferred Embodiment 1 are conducted. Then, as shown in FIG. 5A, a bonding end portion of each projection 15B formed integrally with a copper plate 150 and a bonding end portion of each projection 14A formed integrally with a copper plate 140 are bonded to each other with an insulating resin 24 laminated therebetween, to form a laminate. Hereinafter, a surface of the copper plate 150 which is opposite to a surface thereof on which each projection 15B is formed is referred to as an upper surface. In addition, a surface of the copper plate 140 which is opposite to a surface thereof on which each projection 14A is formed is referred to as a lower surface.

In the next step, as shown in FIG. 5B, projections 15A are formed integrally with the copper plate 150 at positions on the upper surface, which are opposed to the projections 15B, so as to project in the normal direction of the upper surface. In addition, the projections 14B are formed integrally with the copper plate 140 at positions on the lower surface, which are opposed to the projections 14A, so as to project in the normal direction of the lower surface.

Furthermore, as shown in FIG. 5C, pattern formation is conducted on both surfaces of the laminate by a subtractive method, such that a first intermediate layer wiring pattern 14 and a second intermediate layer wiring pattern 15 are formed. In this step, resists remaining on the bonding end portions of the projections 14B and 15A are peeled off.

Subsequently, as shown in FIG. 5D, an insulating resin 25 is applied to the projection 15A side of the laminate, and an insulating resin 26 is applied to the projection 14B side of the laminate. At that time, the projections 15A and 14B are formed into a state of projecting from the insulating resins 25 and 26 by about 0.05 mm, for example.

In the next step, the projections 11A formed integrally with the copper plate 110 and the projections 12A formed integrally with a copper plate 120, which projections 11A and 12A are produced by the manufacturing steps from FIG. 3A to FIG. 3C as described in Preferred Embodiment 1, are further laminated on the laminate produced until FIG. 5D.

In the subsequent step (FIG. 6A), the bonding end portions of the projections 11A and the projections 15A are bonded to each other, and the bonding end portions of the projections 12A and the projections 14B are bonded to each other. The respective bonding end portions are brought into close contact with each other. In this state, these projections are press-bonded by conducting heating and pressurization at 180° C. and 10 MPa for 1 hour.

In the next step (FIG. 6B), pattern formation is conducted on upper and lower surfaces of the press-bonded laminate by a subtractive method, such that an upper wiring pattern 11 and a lower wiring pattern 12 are formed. Thus, a wiring board 2 is formed.

In Preferred Embodiment 2, since the wiring patterns are incorporated into the insulating layer 10 to make the insulating layer 10 multilayered as described above, it is possible to prevent or significantly reduce an increase in the size of the wiring board 2 in the plane direction, and it is possible to achieve size reduction of the wiring board 2.

### Preferred Embodiment 3

Next, a wiring board according to Preferred Embodiment 3 will be described. The wiring board 3 according to Preferred Embodiment 3 is different from Preferred Embodiment 1 in that an electronic component is mounted within the insulating layer of the wiring board according to Preferred Embodiment 1.

FIG. 7 is a schematic cross-sectional view of the wiring board according to Preferred Embodiment 3. Lands 12B preferably are formed integrally with the lower wiring pattern 12 of the wiring board 3 according to Preferred Embodiment 3. An electronic component 15 is mounted on the lands 12B. Thus, since the electronic component 15 is included in the insulating layer 10, it is possible to reduce the size of the wiring board 3.

It should be noted that examples of the electronic component 15 include an active element such as a silicon semiconductor element or a gallium arsenide semiconductor element or a passive element such as a capacitor or an inductor, for example.

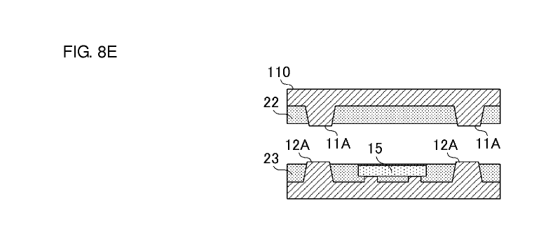

Hereinafter, a non-limiting example of a method for manufacturing the wiring board 3 according to Preferred Embodiment 3 will be described. FIG. 8A, FIG. 8B, FIG. 8C, FIG. 8D, and FIG. 8E are schematic diagrams showing, in sequence, steps for manufacturing the wiring board 3 according to Preferred Embodiment 3.

In an initial first step (FIG. 8A), a dry film resist (not shown) having a thickness of 15 μm is attached to both surfaces of a 0.3 mm-thick copper plate 120 which are opposed to each other in the thickness direction thereof. Then, etching is conducted on one surface of the copper plate 120 such that truncated cone-shaped projections 12A having a diameter of 0.6 mm remain.

Next, in a second step (FIG. 8B), etching is further conducted on the copper plate 120 that has been subjected to the etching in FIG. 8A, to form lands 12B. Since the lands 12B are formed, the length of each projection 12A formed in FIG. 8A is increased by a length equivalent to the amount of the etching for forming the lands 12B. In addition, in this step, the resist that has remained on the bonding end portions of the projections 12A and the lands 12B is peeled off.

In a third step (FIG. 8C), an electronic component 15 is mounted on the formed lands 12B. Then, in a fourth step (FIG. 8D), an insulating resin 23 is laminated on the copper plate 120. The insulating resin 23 is liquid. After the insulating resin 23 is applied onto the copper plate 120, vacuum deaeration is conducted and heating is conducted, such that the electronic component 15 is sealed in a state where the insulating resin 23 is semi-cured. At that time, the projections 12A are formed into a state of projecting from the insulating resin 23 by about 0.15 mm, for example.

In the next step (FIG. 8E), bonding end portions of projections 11A formed integrally with a copper plate 110 in the same manner as in the step described in Preferred Embodiment 1 and bonding end portions of the projections 12A formed until FIG. 8C are brought into close contact with each other. In this state, these projections are press-bonded by conducting heating and pressurization at 180° C. and 10 MPa for 1 hour. Thus, one inter-layer connection conductor 13 obtained by connecting the projections 11A and 12A is formed.

Thereafter, the laminate produced until FIG. 8E is crimped and pressed, and then pattern formation is conducted on both surfaces of the laminate by a subtractive method, such that an upper wiring pattern 11 and a lower wiring pattern 12 are formed. Thus, a wiring board 3 is formed.

In Preferred Embodiment 3, since the electronic component 15 is included in the insulating layer 10 as described above, it is possible to reduce the size of the wiring board 3.

Although the wiring board according to various preferred embodiments of the present invention has been described in detail above, it is possible to appropriately design and change the specific configuration and the like of the wiring board. The operations and the effects described in the above preferred embodiments are merely described as the most preferred operations and the effects provided from the present invention, and the operations and the effects provided by the present invention are not limited to those described in the above preferred embodiments.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. (canceled)

2. A wiring board comprising:
an insulating layer;
a first conductive pattern and a second conductive pattern arranged with the insulating layer interposed therebetween and extending in a plane direction; and
an inter-layer connection conductor extending through the insulating layer in a thickness direction to connect the first conductive pattern and the second conductive pattern; wherein
the inter-layer connection conductor includes portions which are thinned from the first conductive pattern and the second conductive pattern toward the first conductive pattern and the second conductive pattern which are opposed to each other in the thickness direction.

3. The wiring board according to claim 2, wherein the inter-layer connection conductor is defined end portions of two connection conductors which are thinned toward ends thereof being bonded to each other.

4. The wiring board according to claim 3, wherein
one of the two connection conductors is integrally arranged with the first conductive pattern so as to project in the thickness direction at the second conductive pattern side; and
the other of the two connection conductors is integrally arranged with the second conductive pattern so as to project in the thickness direction at the first conductive pattern side.

5. The wiring board according to claim 2, wherein
the first conductive pattern includes a land integrally arranged at the insulating layer side; and
the wiring board includes an electronic component mounted on the land and arranged within the insulating layer.

6. The wiring board according to claim 2, wherein the insulating layer includes only one single layer or a plurality of layers.

7. The wiring board according to claim 2, wherein the insulating layer includes at least one of a glass epoxy resin, an epoxy resin, a phenolic resin, and a cyanate resin.

8. The wiring board according to claim 5, wherein the electronic component is one of an active element and a passive element.

9. The wiring board according to claim 2, wherein the first conductive pattern includes integrally provided projections that project along the thickness direction.

10. The wiring board according to claim 9, wherein the first conductive pattern and the projections are made of the same material and do not contain a bonding interface therebetween.

11. The wiring board according to claim 9, wherein the projections have a truncated cone shape or a square pole shape.

12. The wiring board according to claim 9, wherein the projections have a height that is about ½ of a distance between the first conductive pattern and the second conductive pattern.

13. The wiring board according to claim 2, wherein the second conductive pattern includes integrally provided projections that project along the thickness direction.

14. The wiring board according to claim 13, wherein the second conductive pattern and the projections are made of the same material and do not contain a bonding interface therebetween.

15. The wiring board according to claim 13, wherein the projections have a truncated cone shape or a square pole shape.

16. The wiring board according to claim 13, wherein the projections have a height that is about ½ of a distance between the first conductive pattern and the second conductive pattern.

17. The wiring board according to claim 2, further comprising a first intermediate layer wiring pattern and a second intermediate layer wiring pattern located between the first conductive pattern and the second conductive pattern.

18. The wiring board according to claim 17, wherein each of the first intermediate layer wiring pattern and the second intermediate layer wiring pattern include projections extending in the thickness direction.

19. The wiring board according to claim 18, wherein the first intermediate layer wiring pattern and the corresponding projections are made of the same material and do not contain a bonding interface therebetween, and the second intermediate layer wiring pattern and the corresponding projections are made of the same material and do not contain a bonding interface therebetween.

20. The wiring board according to claim 2, further comprising an electronic component disposed within the insulating layer.

21. The wiring board according to claim 20, wherein the electronic component is an active element or a passive element.
